(19) United States
(12) Patent Application Publication
(10) Pub. No.: US 2012/0285383 A1
(43) Pub. Date: Nov. 15, 2012

(54) MOUNTING FOR FIXING A REACTOR IN A VACUUM CHAMBER

(75) Inventors: Eduard Ilinich, Jona (CH); Andreas Meier, Gamprin (LI)

(73) Assignee: OERLIKON SOLAR AG, TRUBBACH, Trubbach (CH)

(21) Appl. No.: 13/521,971

(22) PCT Filed: Jan. 12, 2011
(86) PCT No.: PCT/EP2011/050344

§ 371 Date: Jul. 12, 2012

Related U.S. Application Data
(60) Provisional application No. 61/294,892, filed on Jan. 14, 2010.

(51) Int. Cl. C23C 14/10

(52) U.S. Cl. 118/728

(57) ABSTRACT

The present invention provides a mounting, configured for fixing a reactor, in particular a PECVD reactor, in a vacuum chamber (1), the mounting (10) comprising a framework of at least two outer beams (11) being arranged opposite to each other, and a plurality of cross beams (12), wherein the outer beams (11) and the cross beams (12) form compartments (13), in which temperature controlling elements are provided. The mounting (10) according to the invention has a reduced weight and is producible cost saving.

### TECHNICAL FIELD

The present invention relates to a mounting, configured for fixing a reactor, in particular a PECVD reactor, in a vacuum chamber. The present invention further relates to a vacuum chamber comprising said mounting.

### BACKGROUND ART

In thin film silicon photovoltaic cell production, for example, the most common process for silicon deposition is plasma enhanced chemical vapour deposition (PECVD). For example, in a parallel plate reactor with two electrodes, a plasma is ignited with the aid of a HF voltage. A silicon comprising gas like silane, often diluted in hydrogen, allows deposition of silicon layers of varying crystallinity. Certain process parameters have to be controlled, such as pressure, gas mixture, power and process temperature. Heating of the plasma reactor occurs essentially due to the plasma discharge. In order to avoid overheating of a substrate to be treated, cooling means are often integrated in a reactor design. However, in the following, “temperature control” or “temperature controlling” addresses both cooling and heating.

A common method for the production of thin film silicon solar cells requires one or more PECVD steps in which the silicon is deposited onto a substrate, for example a glass plate. FIG. 1 shows a schematical view of an arrangement for the production of thin film solar cells. The arrangement comprises one common vacuum chamber 1 having an enclosure 2, in which stacked plasma reactors 4 are provided between and connected to mountings formed as steel plates 3. This arrangement is also known as the Plasmabox principle. Today, up to ten reactors 4 share one vacuum chamber 1, which considerably increases the throughput of such a PECVD tool. A system of that kind, also known as KAI-PECVD deposition tool, is commercially available from Oerlikon Solar.

For a single reactor 4 and even more for a stack of reactors 4 it is important to properly position them in the surrounding vacuum chamber 1 within enclosure 2. Since the reactors 4 need to be held at a certain process temperature, it is necessary to provide a heat sink and a defined temperature surrounding. Further, the reactors 4 have to be mounted and held within the vacuum enclosure 2.

FIG. 2 shows a perspective view of a stack according to the prior art configured to accommodate ten reactors 4. The reactors 4 themselves are omitted in FIG. 2. In this design, the reactors 4 are provided for being both carried and supported by integral steel plates 3, that additionally furnish channels for a temperature control medium, such as water, steam, oil, or alike. According to FIG. 2, eleven plates 3 are provided being stacked with the aid of four columns 5 in the corners of the stack. The steel plates 3, or the channels for the temperature control medium located therein, may be connected by a connector 6, from which conducts 7 are provided for guiding temperature controlling medium into the channels of the steel plates 3. The steel plates 3 furthermore may exhibit grooves 8 and pockets 9 to give room for additional functions, for example space for mounting tools or load/unload robots.

A reactor stack according to the state of the art is difficult to produce for structural reasons. Reinforcing means like bracings or stiffeners may not waste too much space between individual reactors without increasing the overall volume of the chamber 1. It is thus difficult to meet the flatness requirements. Costly manufacturing methods like deep-hole drilling and several flattening steps in the production process result in a very expensive component. In addition, the solution according to the prior art is very heavy, requiring massive tools for transportation and installation of the stack.

In order to make solar technology, for example, economically viable, it is essential to reduce the capital expenditure on the production equipment. Further, savings in material usage of the production equipment decrease the gray energy consumed to make solar panels.

### DISCLOSURE OF INVENTION

It is an object of the present invention to provide a mounting, configured for fixing a reactor, in particular a PECVD reactor, in a vacuum chamber, which overcomes at least one of the deficiencies as set forth above.

It is a particular object of the present invention to provide a mounting, configured for fixing a reactor, in particular a PECVD reactor, in a vacuum chamber, which has a limited weight.

These objects are achieved by a mounting according to claim 1. Advantageous and preferred embodiments are given in the dependent claims.

The present invention relates to a mounting, configured for fixing a reactor, in particular a PECVD reactor, in a vacuum chamber, the mounting comprising a framework of at least two outer beams being arranged opposite to each other, and a plurality of cross beams, wherein the outer beams and the cross beams form compartments, in which temperature controlling elements are provided.

According to the invention, a mounting is provided which is not formed of a continuous steel plate, but which is formed as a framework of beams, or profiles, respectively, as a base structure. The framework provides adequate structural strength and stability resulting in the mounting being stable enough for PECVD purposes, for example.

The framework comprises at least two outer beams, or edge beams, respectively, defining at least to edges of the framework, these edges being opposite edges of the framework. Additionally, cross beams are provided preferably being aligned to be directed essentially perpendicular with respect to the outer beams and being mounted to said outer beams. The outer beams are thus connected to each other by the cross beams.

The framework of beams is configured to carry, or support, reactors, such as PECVD reactors. The beams may thus have grooves for guiding the reactor and further grooves or pockets to give room for additional functions of the reactor e.g. used for substrate handling or mounting purposes.

At the interspaces of the framework, i.e. between the respective beams, compartments are formed, which are used to provide temperature controlling elements. These temperature controlling elements may be used for adjusting an appropriate temperature inside the vacuum chamber and thus at the surrounding of the reactors. For example, the inside of the vacuum chamber or the reactors as such may be cooled, or heated, according to the desired application. Consequently, the temperature controlling elements may be provided with temperature controlling channels for guiding through a temperature controlling medium.

The function of temperature controlling may thus be achieved by thin elements, embedded in the framework of profiles, or beams, respectively. The temperature controlling elements do not have to contribute to the structural stability of the framework, but are supported and positioned by the main framework.

A mounting according to the invention thus distinguishes and separates the functionality of a fixture for reactors and a temperature control element for controlling the temperature of the reactor.

The arrangement according to the invention comprising a framework of respective beams and temperature controlling elements being located between said beams, or inside the framework, respectively, may be more than 50% less heavy compared to mountings according to the prior art having integral plates as shown in FIG. 2. For a stack carrying ten reactors, for example, the weight reduction may be more than 2.800 kg. It is apparent, that such a reduction in weight provides an improved and cost saving production process of a vacuum chamber comprising the mountings according to the invention.

In a preferred embodiment of the present invention, one or more diagonal beams are provided and each diagonal beam is preferably attached to an outer beam and to a cross beam. These beams may be added in order to enhance stiffness and thus the structural integrity of the mounting according to the invention, if necessary. The diagonal beams my proceed from one corner of the mounting, or framework, respectively, to the opposed corner.

In a further preferred embodiment of the present invention, the beams are formed from stainless steel or aluminum. In detail, it is preferred that all beams, i.e. the outer beams, the cross beams as well as the diagonal beams, are formed from the above identified materials. These materials may be chosen to further reduce the weight of the mounting, which is especially the case if the beams are formed from aluminum. Additionally, the beams may have an especially improved structural integrity and thus stability. This is mainly the case if the beams are formed from stainless steel.

In a further preferred embodiment of the present invention, the temperature controlling elements comprise two parallel plates proceeding between the beams, being sealed against the outside at the beams and having an inlet and an outlet for guiding through a temperature controlling medium, in particular a temperature controlling fluid. This is a very simple arrangement for forming the temperature controlling elements which is as well applicable for forming stacks of mountings. Additionally, due to the fact that the whole plates may contribute to the heating or cooling effect to the surrounding, the effectiveness of the temperature controlling elements according to this embodiment is especially improved.

It is furthermore preferred that the temperature controlling elements are connected to the beams by unilateral clamping or by using elastic fixtures. These embodiments exhibit the positive effect, that the temperature controlling elements are affixed to the framework of beams such, that they can expand without negatively affecting the structural integrity of the framework and thus of the overall reactor mount. Consequently, the stability as well as the reliability of a mounting according to the invention may be further improved.

In a further preferred embodiment of the present invention, the framework has a dimension of ≧1 m². The mounting according to the invention is thus especially preferred for reactors and substrates having these dimensions. Especially in this case, problems with respect to sagging may occur and have to be addressed and compensated, or avoided. According to this embodiment, these problems are especially well dealt with.

The invention furthermore relates to a vacuum chamber, in particular to a PECVD chamber wherein the chamber, comprises one or more of the mountings according to the invention as set forth above. A vacuum chamber like described above thus has the advantages like described with respect to the mounting according to the invention.

Accordingly, a vacuum chamber according to the invention has a reduced weight and may thus be prepared easy and cost saving.

In a preferred embodiment of the vacuum chamber according to the present invention, a plurality of mountings is provided being connected to a plurality of columns and forming a stack of mountings. Especially by providing a plurality of mountings, a high throughput may be realized allowing an adequate effectiveness of a process, for example a PECVD process being performed in the vacuum chamber according to the invention. Additionally, by forming a stack in which the mountings are connected to a plurality of columns, the structural integrity and thus the stability of the stack is improved. A column shall thereby mean any elongated connecter to which the mountings may be fixed.

### BRIEF DESCRIPTION OF DRAWINGS

These and other aspects of the invention will be apparent from and elucidated with reference to the embodiments described hereinafter.

In the drawings:

FIG. 1 shows a schematic view of an arrangement for the production of solar cells according to the prior art;

FIG. 2 shows a schematic perspective view of a stack foreseen to accommodate ten reactors according to the prior art;

FIG. 3a shows a schematic perspective top view of an embodiment of a mounting according to the invention;

FIG. 3b shows a respective sketch to show the essential elements of the embodiment according to FIG. 3a;

FIG. 4a shows a schematic perspective bottom view of an embodiment of a mounting according to the invention;

FIG. 4b shows a respective sketch to show the essential elements of the embodiment according to FIG. 4a; and

FIG. 5 shows a schematic perspective top view on a stack of mountings according to the invention.

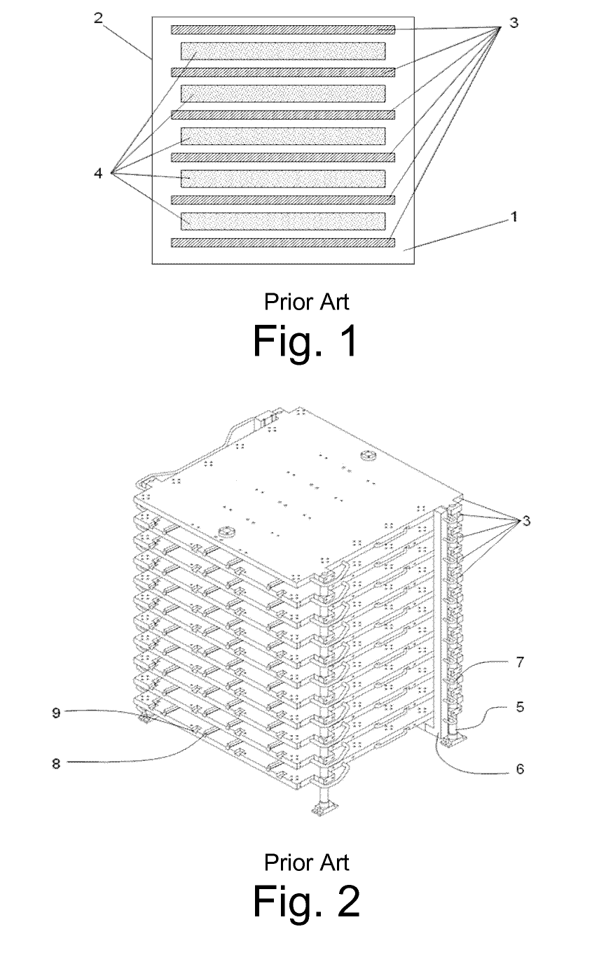

### DETAILED DESCRIPTION OF DRAWINGS

In the following, a fixture, or mounting 10, according to the invention is described. In detail, the mounting 10 is configured for fixing a reactor, such as a plasma reactor, particularly a PECVD parallel plate reactor, in a vacuum chamber. The reactor, which may include a temperature control device for cooling or heating a substrate, may be one known from the state of the art and is not shown in the following figures.

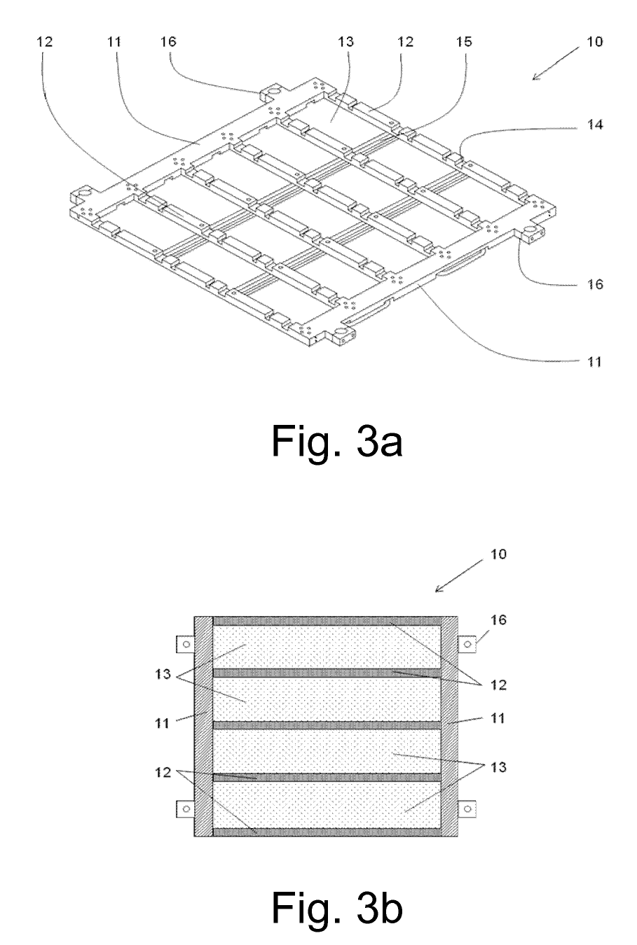

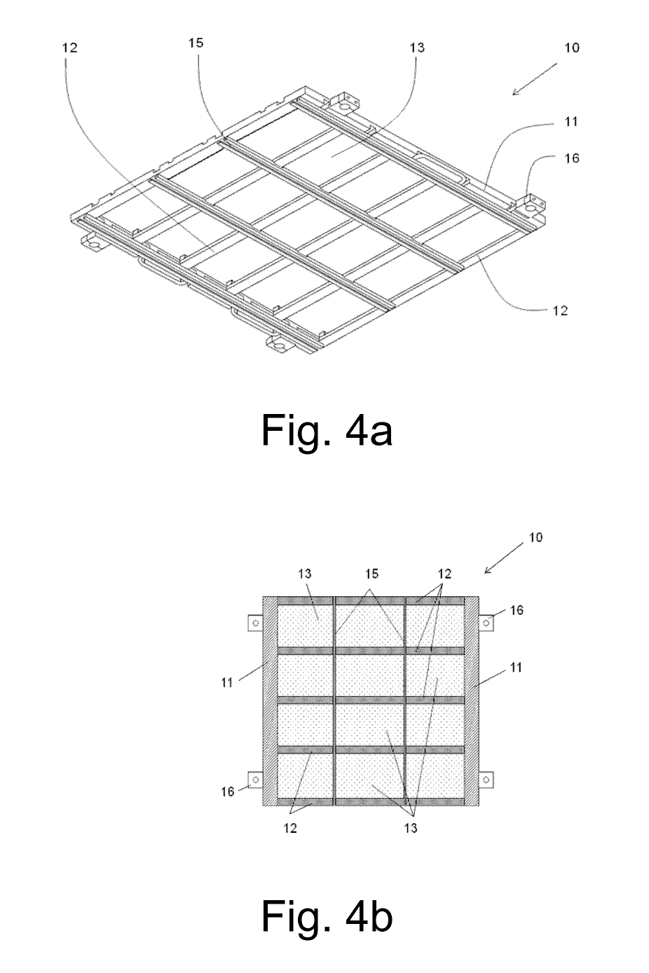

The mounting 10 according to the invention is shown in detail in FIGS. 3a and 3b as well as in FIGS. 4a and 4b. It comprises at least two edge beams, or outer beams 11, respectively, being arranged at two opposite outer edges of the mounting 10, and a plurality of more than two cross beams 12 mounted to said outer beams 11. Consequently, the outer beams 11 and the cross beams 12 form a grid, or framework, respectively, which can alternatively be realized by four outer beams 11 and a series of cross beams 12. The cross beams 12 may be arranged in parallel with respect to each other or crosswise. In the first case, the cross beams may be arranged perpendicular with respect to the outer beams 11. Diagonal beams, or diagonal bars or riders, respectively, may be added in order to enhance the stiffness, if necessary.

Essentially, however, it is preferred to use as few and as identical parts as possible. Additionally, it is preferred to use the same profiles for the outer beams 11, the cross beams 12 as well as the diagonal beams. Beams 11, 12, as well as the diagonal beams preferably may be made from extruded aluminum or stainless steel. They may be mounted, or connected, to each other by a screwing connection, a welded connection, or another appropriate connection.

For a further cost reduction, the framework, or the beams 11, 12, respectively, may be made out of cast steel protected from etching gases by a protective coating or made out of cast aluminum.

It can be seen that the outer beams 11 and the cross beams 12, and eventually the diagonal beams, form compartments 13, or pockets, respectively, between them. Consequently, the compartments 13 are formed as interspaces between the beams 11, 12. According to the invention, the compartments 13, preferably each compartment 13, are used to accommodate temperature controlling elements. The individual temperature controlling elements are preferably connected in series. They may be designed, for example, as two parallel thin plates, or two sheets, for example from stainless steel, sealed at their edges and thus at the beams 11, 12 for example by welding, so that a cavity is formed. They may comprise an inlet and an outlet for a temperature controlling medium, used to control the temperature. In detail, an appropriate temperature controlling medium may be a fluid such as water, steam, or oil. An operating pressure of 6 bars and a flow rate of 4 liters/min, for example may be appropriate. According to this, the temperature of the substrate can be kept between 150° C. and 300° C. during operation conditions, e.g. at a PECVD process.

Alternatively, a pipe may be arranged as a flat coil, which in turn may be connected to a flat piece of thermally conductive material. Other ways to design an essentially flat cooling or heating plate may include passive, i.e. absorbing or compensating devices, electrical heating/cooling elements or even cooling gas distribution grids directed towards the reactor top or bottom respectively. Connecting pipes, cables or other piping as well as control units, for example for in-situ temperature measurements, can be integrated in grooves or pockets of the beams 11 12. The temperature controlling elements are preferably affixed to the framework of beams 11, 12 such, that they can expand without negatively affecting the structural integrity of the overall mounting 10. This can be achieved by unilateral clamping or elastic fixtures, for example.

The temperature controlling elements preferably are designed to allow and/or control temperatures between 100° C. to 500° C., preferably between 150° C. and 300° C., especially preferred between 180° C. and 250° C. A coating with high emissivity increases the absorption of radiated heat and increases the performance of the heat sink, or temperature controlling elements, respectively.

The mounting 10 according to the invention has to withstand both the temperature controlling medium, for example water, steam, oil, as well as the corrosive effects of cleaning gases, or etching gases, respectively, which may occur during a PECVD process, for example, and which often may comprise fluorine radicals.

In a preferred embodiment of the present invention the framework has a size, lying the range of ≧1 m². In an especially preferred embodiment, the framework has a size of 1.4 m². This allows the mounting 10 to be designed for substrates having a size, or dimensions, in the range of ≧1 m², in particular of 1.4 m².

The mounting 10 is designed for accommodating reactors, such as PECVD reactors. The reactors may be not vacuum tight, but allow controlling the plasma parameters in a dedicated, small volume. Each reactor has its own electrical connectors and working gas supply. Residuals of the PECVD or etching process are removed by means of pumps, not shown as such, which are connected to a common enclosure.

For guiding the reactors in the desired position, the framework, for example the cross beams 12, may have grooves 14, in which respective projections of the reactors may be located. The grooves 14 are shown in FIG. 3a. Alternatively, or additionally, tracks 15 may be provided for mounting, or hanging, the reactors in the mounting 10. The tracks 15 are shown in FIG. 4b and may be formed as U-shaped bars, for example.

Consequently, reactors can be mounted stationary on the upper side of each reactor mounting 10. In this case, the reactors may be positioned in grooves 14. Alternatively, reactors can be mounted stationary on the lower side of each reactor mounting 10. In this case, the reactors may be positioned in tracks 15.

Additionally, the beams 11, 12 can be equipped, next to the grooves 14 and/or tracks 15, with further grooves or pockets to give room for additional functions, for example space for mounting tools or load/unload robots.

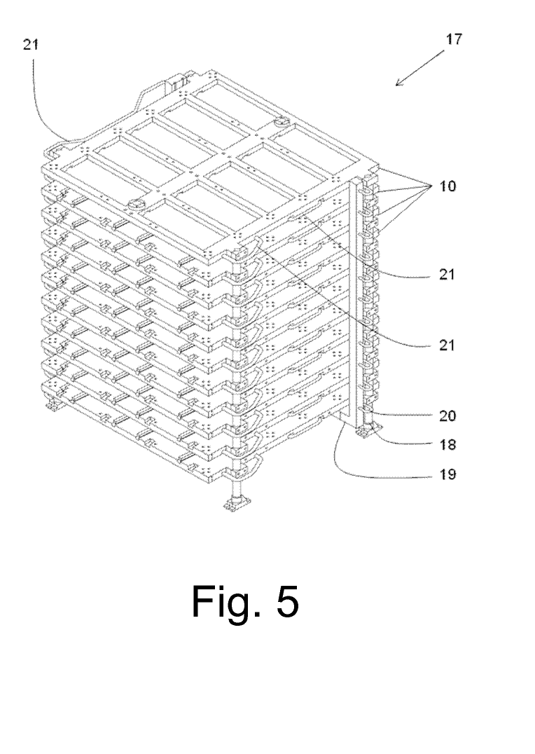

The mounting 10 may be equipped with fixing devices 16. Due to the fixing devices 16, a stack 17 of mountings 10 may be formed to be positioned in a vacuum chamber. In this case, the stack 17 comprises mountings 10 according to the invention, i.e. like described above. Such a stack 17 is shown in FIG. 5. The stack 17 as shown in FIG. 5 is established by, or based on, respectively, columns 18, connecting a plurality of mountings 10 via said fixing devices 16, which preferably are connected to each corner of the respective mountings 10.

The mountings 10 may be connected by a connector 19, from which conducts 20 are provided for guiding temperature controlling medium into respective channels of the mountings 10 and furthermore in the temperature controlling elements.

A stack 17 accommodating ten reactors comprises therefore eleven reactor mountings 10. These mountings 10 may be held by four columns 18 and fixing devices 16, preferably made from stainless steel, for example high-grade or high quality steel. Preferably, said stainless steel exhibits a very low linear expansion coefficient in order to reduce the length variation of the reactor stack. According to FIG. 5, each reactor mount 10 exhibits two outer beams 11 lengthwise and six cross beams 12. Both outer beams 11 and cross beams 12 are made from stainless steel and being screwed together.

The reactors itself, not shown as such, can be inserted into the stack 17 by placing them between adjacent mountings 10. In a preferred embodiment, the reactors are arranged in a suspended way. This can for example be achieved by the tracks 15, for example in the form of U-shaped bars, mounted to the lower side of the reactor mounting 10, for example, which may be seen in FIG. 4b. With an appropriate counterpart, a drawer-like design can be achieved, thus simplifying as well assembly and exchange and/or maintenance of reactors.

Since every reactor may be designed independently from the other reactors and thus the reactors independently contain electrodes, such as plate-like electrodes, gas distribution showerheads and substrate support, the temperature control function of the reactor mounting 10 affects both sides of each reactor and thus allows to precisely control the temperature of the reactor. The temperature controlling elements of each individual mounting 10 may be serially connected, or connected in parallel, for example by conducts 21. Then, advantageously, the main temperature controlling medium supply will be arranged in close relationship to one of the columns 19, which may be seen in FIG. 5.

This example shall not be understood to be limiting, the inventive modular assembly can be used with different substrate sizes and other numbers of beams without leaving the scope of the invention.

While the invention has been illustrated and described in detail in the drawings and foregoing description, such illustration and description are to be considered illustrative or exemplary and not restrictive; the invention is not limited to the disclosed embodiments. Other variations to be disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting scope.

REFERENCE SIGN LIST

1 vacuum chamber

2 enclosure

3 steel plate

4 reactor

5 column

6 connector

7 conduct

8 groove

9 pocket

10 mounting

11 outer beam

12 cross beam

13 compartment

14 groove

15 rack

16 fixing device

17 stack

18 column

19 connector

20 conduct

21 conduct

1. Mounting, configured for fixing a reactor, in particular a PECVD reactor, in a vacuum chamber (1), the mounting (10) comprising a framework of at least two outer beams (11) being arranged opposite to each other, and a plurality of cross beams (12), wherein the outer beams (11) and the cross beams (12) form compartments (13), in which temperature controlling elements are provided.

2. Mounting according to claim 1, wherein the beams (11, 12) are formed from stainless steel or aluminum.

3. Mounting according to claim 1, wherein the temperature controlling elements comprise two parallel plates proceeding between the beams (11, 12) and being sealed against the outside at the beams (11, 12) and having an inlet and an outlet for guiding through a temperature controlling medium, in particular a temperature controlling fluid.

4. Mounting according to claim 1, wherein the temperature controlling elements are connected to the beams (11, 12) by unilateral clamping or by using elastic fixtures.

5. Mounting according to claim 1, wherein the framework has a dimension of ≧1 m².

6. Vacuum chamber, in particular PECVD chamber, wherein the chamber (1) comprises one or more of the mountings (10) according to claim 1.

7. Vacuum chamber according to claim 6, wherein a plurality of mountings (10) is provided being connected to a plurality of columns (18) and forming a stack (17) of mountings (10).
